(19) United States
(12) Patent Application Publication
(10) Pub. No.: US 2011/0232943 A1
(43) Pub. Date: Sep. 29, 2011

(54) MULTILAYER WIRING BOARD

(75) Inventors: Toshinori HIDA, Kani-shi (JP); Kazunaga HIGO, Inuyama-shi (JP); Hironori SATO, Kasugai-shi (JP)

(73) Assignee: NGK SPARK PLUG CO., LTD., Nagoya-shi (JP)

(21) Appl. No.: 13/052,246

(22) Filed: Mar. 21, 2011

(30) Foreign Application Priority Data
Mar. 29, 2010 (JP) 2010-074799
Jan. 21, 2011 (JP) 2011-010926

(51) Int. Cl. H05K 1/02

(52) U.S. Cl. 174/251

(57) ABSTRACT

There is provided a multilayer wiring board, which has a board body formed with two opposite main surfaces and includes a first resin insulating layer, a second resin insulating layer laminated to the first resin insulating layer and a wiring pattern arranged between the first and second resin insulating layers with a first surface of the wiring pattern abutting the first resin insulating layer and a second surface of the wiring pattern abutting the second resin insulating layer. The multilayer wiring board is characterized in that the wiring pattern extends in a plane direction of the board body and is embedded in both of the first and second resin insulating layers.

### BACKGROUND OF THE INVENTION

The present invention relates to a multilayer wiring board in which a fine wiring pattern is formed between two adjacent resinous insulating layers.

In recent years, it has been demanded to achieve high density mounting of electronic components on wiring boards for size reduction and performance improvement of electronic equipment. Great importance is being placed on the adoption of a wiring board with a multilayer structure in order to achieve high density mounting of electronic components. One example of such a multilayer wiring board is a so-called build-up wiring board having a core substrate with a through hole etc. and a build-up layer in which conductive layers and resin insulating layers are alternately laminated together on one side or both sides of the core substrate. In the multilayer wiring board, the conductive layer is generally formed with a fine wiring pattern by semi-additive process. The semi-additive process is known as a series of the following steps: forming via conductor holes in a resin insulating layer, applying an electroless metal plating, a plating resist and an electrolytic metal plating successively to the resin insulating layer, removing the plating resist, and then, etching unnecessary portions of the electroless metal plating as disclosed in Japanese Laid-Open Patent Publication No. 2000-188460.

### SUMMARY OF THE INVENTION

In the above conventional multilayer wiring board, the metal plating is adhered to the resin insulating layer by the anchoring effect of a roughened surface of the resin insulating layer at the time of removal of the unnecessary plating resist. The resulting wiring pattern of the metal plating is thus merely mounted on the resin insulating layer. Further, there is a growing demand to form a finer wiring pattern with e.g. a line width of 20 μm or less (preferably 10 μm or less) in the build-up layer. This leads to increase in the height-to-width dimension ratio of the wiring pattern and decrease in the area of contact of the wiring pattern with the resin insulating layer so that the wiring pattern becomes structurally unstable. The multilayer wiring board deteriorates in reliability and yield as the wiring pattern cannot be held in contact with the resin insulating layer and falls down to or gets separated from the resin insulating layer due to insufficient adhesion between the wiring pattern and the resin insulating layer.

In addition, the roughness of the wiring pattern ripples through the resin insulating layer in the conventional multilayer wiring board. If the metal plating is made smaller in thickness so as to avoid such pattern roughness, the via conductor holes may not sufficiently be filled with the metal plating. The metal plating is thus applied to a given thickness with a higher priority given to the proper formation of the via conductors than the thickness reduction of the metal plating. As a result, the wiring pattern increases in thickness and causes increases in the roughness of the outermost surface of the wiring board and in the thickness variations of the resin insulating layer.

It is therefore an object of the present invention to provide a multilayer wiring board having formed therein a fine wiring pattern that can attain high resistance to fall-down and separation and good contact with resin insulating layers.

According to an aspect of the present invention, there is provided a multilayer wiring board, comprising: a board body formed with two opposite main surfaces and including a first resin insulating layer, a second resin insulating layer laminated to the first resin insulating layer and a wiring pattern arranged between the first and second resin insulating layers with a first surface of the wiring pattern abutting the first resin insulating layer and a second surface of the wiring pattern abutting the second resin insulating layer, the wiring pattern extending in a plane direction of the board body and being embedded in both of the first and second resin insulating layers.

The other objects and features of the present invention will also become understood from the following description.

### BRIEF DESCRIPTION OF THE DRAWINGS

FIG. 1 is a schematic section view of a multilayer wiring board according to a first embodiment of the present invention.

FIG. 2 is an enlarged section view showing the arrangement of a wiring pattern in the multilayer wiring board according to the first embodiment of the present invention.

FIGS. 3 to 10 are schematic section views of a method for manufacturing the multilayer wiring board according to the first embodiment of the present invention.

FIG. 11 is an enlarged section view of substantial part of a multilayer wiring board according to a second embodiment of the present invention.

FIG. 12 is an enlarged section view of substantial part of a multilayer wiring board according to a third embodiment of the present invention.

FIG. 13 is an enlarged plan view of substantial part of a multilayer wiring board according to a fourth embodiment of the present invention.

FIG. 14 is an enlarged plan view of substantial part of a multilayer wiring board according to a fifth embodiment of the present invention.

FIGS. 15 to 17 are schematic section views of a method for manufacturing a multilayer wiring board according to a sixth embodiment of the present invention.

### DESCRIPTION OF THE EMBODIMENTS

The present invention will be described in detail below by way of the following embodiments, in which like parts and portions are designated by like reference numerals to avoid repeated explanations thereof.

### First Embodiment

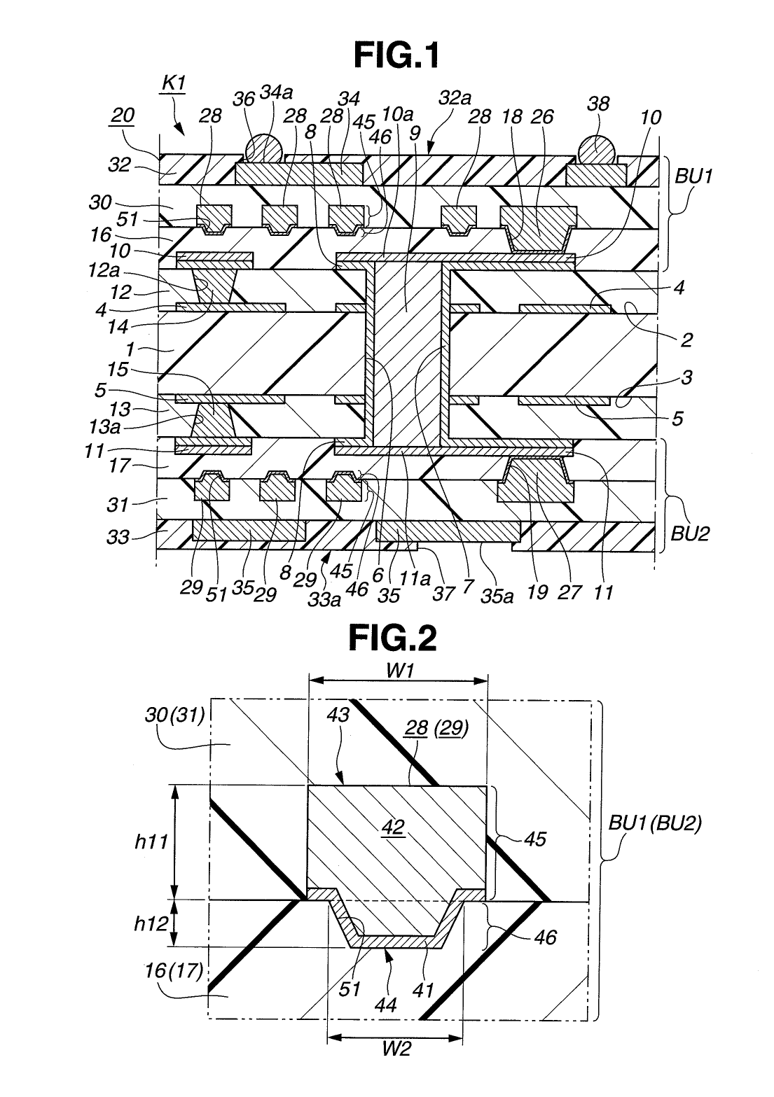

A multilayer wiring board K1 according to the first embodiment of the present invention will be explained below with reference to FIGS. 1 to 10.

As shown in FIG. 1, the multilayer wiring board K1 is designed as a build-up multilayer wiring board in which two build-up layers BU1 and BU2 are located on both sides of a core substrate 1. Hereinafter, the term “inner” refers to a side nearer to the core substrate 1; and the term “outer” refers to a side opposite the inner side. These terms are used to simply for the purpose of describing positional relationships in the drawings and are not construed as limiting the present invention to particular orientations.

More specifically, the multilayer wiring board K1 has a board body 20 formed with two opposite main surfaces 32a and 33a and including a core substrate 1, resin insulating layers 12 and 13, conductive layers 4 and 5, build-up layers BU1 and BU2, solder resists 32 and 33 and a solder bump 38.

The core substrate 1 is formed into a plate shape with two main surfaces 2 and 3.

The resin insulating layers 12 and 13 are arranged on the main surfaces 2 and 3 of the core substrate 1, respectively.

The conductive layer 4 is arranged between an inner surface of the resin insulating layer 12 and the main surface 2 of the core substrate 1, whereas the conductive layer 5 is arranged between an inner surface of the resin insulating layer 13 and the main surface 3 of the core substrate 1.

The build-up layers BU1 and BU2 are arranged on outer surfaces of the resin insulating layers 12 and 13, respectively. The build-up layer BU1 has a laminated structure in which resin insulating layers 16 and 30 and conductive layers 10, 28 and 34 are alternately laminated to one another. The build-up layer BU2 also has a laminated structure in which resin insulating layers 17 and 31 and conductive layers 11, 29 and 35 are alternately laminated to one another.

It is noted that, as the conductive layers 4, 5, 10, 11, 28, 29, 34 and 35 are each formed with a predetermined wiring pattern, the conductive layers 4 and 5 are referred to as “innermost wiring patterns”; the conductive layers 10, 11, 28 and 29 are referred to as “inner wiring patterns”; and the conductive layers 34 and 35 are referred to as “outer wiring patterns” for the purpose of illustration.

A via conductor hole 12a is formed through the resin insulating layer 12; and a via conductor 14 is filled in the via conductor hole 12a for conduction between the inner wiring pattern 10 and the innermost wiring pattern 4. A via conductor hole 18 is formed through the resin insulating layer 16; and a via conductor 26 is filled in the via conductor hole 18 for conduction between the inner wiring patterns 10 and 28.

A via conductor hole 13a is formed through the resin insulating layer 13; and a via conductor 15 is filled in the via conductor hole 13a for conduction between the inner wiring pattern 11 and the innermost wiring pattern 5. A via conductor hole 19 is formed in the resin insulating layer 17; and a via conductor 27 is filled in the via conductor hole 19 for conduction between the inner wiring patterns 11 and 29.

The solder resist 32 is arranged on an outer surface of the build-up layer BU1 so as to cover the whole of the outer wiring pattern 34 formed on the resin insulating layer 30. Openings 36 are formed in the solder resist 32 at positions corresponding to given regions of the outer wiring pattern 34 (i.e. lands 34a) so that the lands 34a are exposed at the main surface 32a of the wiring board K1 through the openings 36. The solder bumps 38 are formed on the lands 34a so as to protrude outwardly from the main surface 32a of the wiring board K1 for solder joint with an electronic component such as an IC chip (not shown).

The solder resist 33 is arranged on an outer surface of the build-up layer BU2 so as to cover the whole of the outer wiring pattern 35 formed on the resin insulating layer 31. Openings 37 are formed in the solder resist 33 at positions corresponding to given regions of the outer wiring pattern 35 (i.e. lands 35a) so that the lands 35a are exposed at the second main surface 33a of the wiring board K1 through the openings 37 for electrical connection to a printed wiring board such as a mother board.

Further, the wiring board K1 (board body 20) has a through hole structure including a through hole 6 formed through the core substrate 1 and the resin insulating layers 12 and 13, a cylindrical through hole conductor 7 deposited on an inner circumferential surface of the though hole 6 and a resin filler 9 filled in a cylindrical hollow portion of the through hole conductor 7 as shown in FIG. 1 so as to allow conduction between the conductive portions of the build-up layers BU1 and BU2 through the through hole conductor 7. The through hole conductor 7 has conductive portions 8 extending on the outer surfaces of the resin insulating layers 12 and 13.

As shown in FIGS. 1 and 2, the multilayer wiring board K1 of the first embodiment is characterized in that: the inner wiring pattern 28 is sandwiched between the two adjacent resin insulating layers 16 and 30 and embedded in both of these two adjacent resin insulating layers 16 and 30; and the inner wiring pattern 29 is sandwiched between the two adjacent resin insulating layers 17 and 31 and embedded in both of these two adjacent resin insulating layers 17 and 31. In the first embodiment, each of the inner wiring patterns 28 and 29 is preferably formed as a fine wiring pattern with a maximum width of 20 μm or smaller, and more specifically, a line width of 15 μm or smaller and a line spacing of 15 μm or smaller.

The inner wiring pattern 28 extends in a plane direction of the wiring board K1 (board body 20) and has an inner surface 44 abutting an outer surface of the resin insulating layer 16 and an outer surface 43 abutting an inner surface of the resin insulating layer 30. A protruding ridge 46 is formed, as an inner conductive portion, on the center of the inner surface 44 of the inner wiring pattern 28. In the first embodiment, the protruding ridge 46 of the inner wiring pattern 28 is substantially uniform in width along a wiring direction of the inner wiring pattern 28. On the other hand, a groove 51 is recessed in the outer surface of the resin insulating layer 16 along the wiring direction of the inner wiring pattern 28. The inner wiring pattern 28 is embedded in both of the two adjacent resin insulating layers 16 and 30, with the protruding ridge 46 of the inner wiring pattern 28 fitted in the groove 51 of the resin insulating layer 16 and the remaining conductive portion 45 of the inner wiring pattern 28 totally covered with the resin insulating layer 30.

Similarly, the inner wiring pattern 29 extends in a plane direction of the wiring board K1 (board body 20) and has an inner surface 44 abutting an outer surface of the resin insulating layer 17 and an outer surface 43 abutting an inner surface of the resin insulating layer 31. A protruding ridge 46 is formed, as an inner conductive portion, on the center of the inner surface 44 of the inner wiring pattern 29. The protruding ridge 46 of the inner wiring pattern 29 is also substantially uniform in width along a wiring direction of the inner wiring pattern 29. Further, a groove 51 is recessed in the outer surface of the resin insulating layer 17 along the wiring direction of the inner wiring pattern 29. The inner wiring pattern 29 is embedded in both of the two adjacent resin insulating layers 17 and 31, with the protruding ridge 46 of the inner wiring pattern 29 fitted in the groove 51 of the resin insulating layer 17 and the remaining conductive portion 45 of the inner wiring pattern 29 totally covered with the resin insulating layer 31.

It is therefore possible to hold the inner wiring pattern 28, 29 in contact with not only the outer adjacent resin insulating layer 30, 31 but also the inner adjacent resin insulating layer 16, 17 assuredly so that the inner wiring pattern 28, 29, even when it is fine, can be prevented from fall-down and separation and show sufficient adhesion to both of the inner adjacent resin insulating layer 16, 17 and the outer adjacent resin insulating layer 30, 31. Accordingly, the multilayer wiring board K1 is high in reliability and yield.

In the first embodiment, the protruding ridge 46 of the inner wiring pattern 28, 29 and the groove 51 of the resin insulating layer 16, 17 are formed along the wiring direction of the inner wiring pattern 28, 29 in such a manner that the area of cross section of the inner wiring pattern 28, 29 perpendicular to the wiring direction (direction of extension) of the inner wiring pattern 28, 29 is substantially uniform as mentioned above. It is thus possible to set the electrical resistance of the inner wiring pattern 28, 29 constant along the wiring direction of the inner wiring pattern 28, 29.

Furthermore, surface roughness is less likely to occur on the outer adjacent resin insulating layer 30, 31 as the protruding ridge 46 of the inner wiring pattern 28, 29 is embedded in the groove 51 of the inner adjacent resin insulating layer 16, 17. It is thus possible to decrease the thickness variations of the outer adjacent resin insulating layer 30, 31 and thereby possible to improve the flatness of a IC-chip mounting region of the wiring board K1.

There is no particular limitation of the height ratio h11:h12 of the inner wiring pattern 28, 29 where h11 is the height of the outer conductive portion 45 of the inner wiring pattern 28, 29 embedded in the resin insulating layer 30, 31; and h12 is the height of the inner conductive portion (protruding ridge 46) of the inner wiring pattern 28, 29 embedded in the resin insulating layer 16, 17. The height ratio h11:h12 of the inner wiring pattern 28, 29 is preferably in the range of 1:9 to 8:2. When the height ratio h1:h2 is in the above preferable range, the inner wiring pattern 28, 29 can be held in contact with the adjacent resin insulating layers 16, 17 and 30, 31 more assuredly. In particular, the height 12 is preferably 5 μm or larger. In the first embodiment, the inner wiring pattern 28, 29 has a height h11 of about 15 μm and a height h12 of about 5 μm so that the height ratio of the inner wiring pattern 28, 29 is in the above preferable range (h11:h12=15:5).

The depth of the groove 51 (the height h12 of the protruding ridge 46) is preferably smaller than the thickness T1 of the resin insulating layer 16, 17. If the depth of the groove 51 is larger than or equal to the thickness T1 of the resin insulating layer 16, 17, the protruding ridge 46 of the inner wiring pattern 28, 29 passes through the resin insulating layer 16, 17 and may come into contact with the adjacent inner wiring pattern 10, 11. In this case, the wiring patterns 28 and 29 need to be formed at positions that avoid the wiring patterns 10 and 11 in order for the resin insulating layer 16, 17 to provide proper insulation between the wiring patterns 28 and 10 and between the wiring patterns 29 and 11 while allowing conduction between the wiring pattern 28, 29 and the wiring pattern 10, 11 through the via conductor 26, 27. This results in deterioration of flexibility in wiring arrangement and board design. In addition, it is difficult to apply metal plating etc. to the narrow, deep groove 51 for the formation of the wiring pattern 28, 29 (protruding ridge 46). In the first embodiment, the resin insulating layer 16, 17 has a thickness T1 of about 30 μm, which is larger than the height h12 of the inner conductive portion (protruding ridge 46) of the inner wiring pattern 28, 29, or equivalently, the depth of the groove 51, so that the protruding ridge 46 of the inner wiring pattern 28, 29 does not pass through the resin insulating layer 16, 17 and does not come into contact with the inner wiring pattern 10, 11.

In the case where the via conductor 26, 27 is formed in the inner adjacent resin insulating layer 16, 17, the depth of the groove 51 is preferably smaller than the depth of the via conductor hole 18, 19 (the height of the via conductor 26, 27).

There is also no particular limitation of the maximum width ratio W1:W2 of the inner wiring pattern 28, 29 where W1 is the maximum width of the outer conductive portion 45 of the inner wiring pattern 28, 29 embedded in the resin insulating layer 30, 31; and W2 is the maximum width of the protruding inner conductive portion (protruding ridge 46) of the inner wiring pattern 28, 29 embedded in the resin insulating layer 16, 17. The maximum width ratio W1:W2 of the inner wiring pattern 28, 29 is preferably in the range of 1:1 to 9:1. When the maximum width ratio W1:W2 is in the above preferable range, the inner wiring pattern 28, 29 can be held in contact with the inner adjacent resin insulating layer 16, 17 more assuredly. In the first embodiment, the inner wiring pattern 28, 29 has a maximum width W1 of about 15 μm and a maximum width W2 of about 10 μm so that the maximum width ratio of the inner wiring pattern 28, 29 is in the above preferable range (W1:W2=15:10).

Moreover, there is no particular limitation on the taper ratio of the inner conductive portion (protruding ridge 46) of the inner wiring pattern 28, 29 when viewed in cross section perpendicular to the wiring direction of the inner wiring pattern 28, 29. The taper ratio of the inner conductive portion (protruding ridge 46) of the inner wiring pattern 28, 29 is preferably in the range of 80% or higher. The term “taper ratio” herein refers to a value obtained by dividing a shorter one of two parallel sides of the cross section of the inner conductive portion (protruding ridge 46) of the inner wiring pattern 28, 29 by a longer one of the two parallel sides of the cross section of the inner conductive portion (protruding ridge 46) of the inner wiring pattern 28, 29, followed by multiplying by 100. If the taper ratio is lower than 80%, it may be difficult to maintain sufficient contact of the inner wiring pattern 28, 29 with the inner resin insulating layer 16, 17. In the first embodiment, the taper ratio of the protruding ridge 46 is set to about 85%.

The outer surface of the resin insulating layer 16, 17, on which the inner wiring pattern 28, 29 is formed, is preferably roughened rather than smoothened. The inner surface of the groove 51, in which the protruding ridge 46 of the inner wiring pattern 28, 29 is fitted, is also preferably roughened rather than smoothened. It is possible to maintain sufficient contact of the inner wiring pattern 28, 29 with the resin insulating layer 16, 17 more assuredly by the anchoring effect of such roughened surfaces. The surface roughness Ra of the outer surface of the resin insulating layer 16, 17 and the inner surface of the groove 51 can be set to e.g. 1 μm or greater, preferably 1 to 3 μm. Further, the depth of the groove 51 is preferably set larger than the surface roughness Ra of the outer surface of the resin insulating layer 16, 17 and the inner surface of the groove 51.

Herein, there is no particular limitation on the material of the core substrate 1. In the core substrate 1 is composed predominantly of a bismaleimide-triazine resin (BT resin).

The resin insulating layers 12, 13, 16, 17, 30 and 31 can be formed of e.g. a thermosetting resin. Suitable examples of the thermosetting resin are epoxy resins (EP resins), polyimide resins (PI resins), bismaleimide-triazine resins (BT resins), phenol resins, xylene resins, polyester resins and silicon resins. Among others, EP resins, PI resins and BT resins are preferred. The EP resins are suitably of so-called bisphenol (BP) type, phenol novolak (PN) type or cresol novolak (CN) type. It is particularly preferable that the resin material of the resin insulating layer 12, 13, 16, 17, 30, 31 is predominantly composed of an epoxy resin of BP type. Among various BP type epoxy resins, epoxy resins of bisphenol A (BPA) type and bisphenol F (BPF) type are most preferred. The resins of any adjacent two of the resin insulating layers 12, 13, 16, 17, 30 and 31 can be of the same kind or can be of different kinds from each other. The resin material of the resin insulating layer 12, 13, 16, 17, 30, 31 may contain an inorganic filler or organic filler as needed. In the first embodiment, a so-called build-up material is used for formation of not only the resin insulating layers 16, 17, 30 and 31 but also the resin insulating layers 12 and 13. As the build-up material, there can suitably be used an insulating film in which an inorganic filler is dispersed in a thermosetting epoxy resin.

The conductive layers 4 and 5 can be formed from any conductive wiring material such as metal foil. Each of the conductive layers 4 and 5 is formed from copper foil in the first embodiment as will be mentioned later.

On the other hand, the wiring patterns 10, 11, 28, 29, 34 and 35 can be each in the form of a plating layer. There is no particular limitation on the plating layer. Suitable examples of the plating layer are a copper plating layer, a nickel plating layer, a gold plating layer, a silver plating layer, an aluminum plating layer, a zinc plating layer, a cobalt plating layer and a titanium plating layer.

The inner wiring patterns 28 and 29, which are embedded in both of the two adjacent resin insulating layers 16, 17 and 30, 31 according to the present invention, are preferably by copper plating in view of the conductivity, cost performance and workability. It is particularly preferable that each of the inner wiring patterns 28 and 29 has a laminated structure in which an electrolytic copper plating layer 42 is laminated on an electroless copper plating layer 41 as shown in FIGS. 1 and 2.

The above-structured multilayer wiring board K1 of the first embodiment can be produced by the following procedure.

A substrate of bismaleimide-triazine resin (BT resin) with copper foil adhered to both main surfaces thereof is prepared as the core substrate 1. The copper foil is patterned by any known technique such as subtractive process, thereby forming the wiring patterns 4 and 5 on the main surfaces 2 and 3 of the core substrate 1. Thermosetting insulating resin films, in each of which an inorganic filler is dispersed in a thermosetting epoxy resin (EP resin), are applied as the resin insulating layers 12 and 13 onto the main surfaces 2 and 3 of the core substrate 1 so as to cover the wiring patterns 4 and 5. The via conductor holes 12a and 13a are next formed through the resin insulating layers 12 and 13. The through hole 6 is also formed through the core substrate 1 and the resin insulating layers 12 and 13. After that, electroless copper plating and electrolytic copper plating are successively applied to form the through hole conductor 7 in the through hole 6 and to form the via conductors 14, 15 in the via conductor holes 12a and 13a. A paste of the resin filler 9 is filled in the hollow portion of the through hole conductor 7. Electrolytic copper plating is further applied to the copper plating layers of the through hole conductor 7 and the via conductors 14 and 15. At this time, both of end faces of the resin filler 9 are covered with copper plating 10a and 11a.

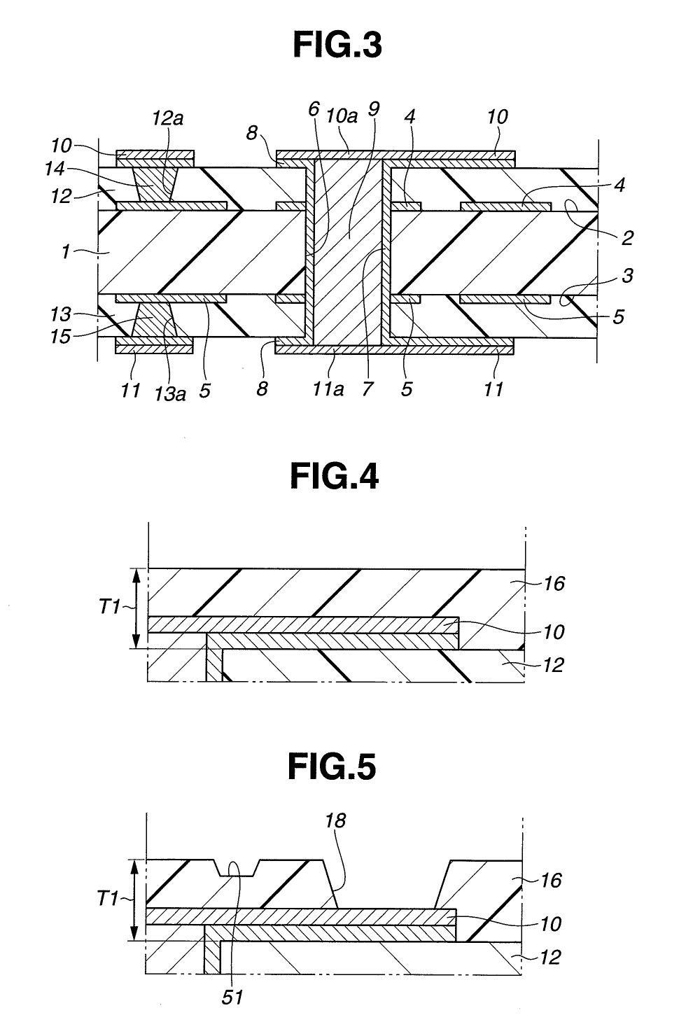

Subsequently, the laminated two copper plating layers are each etched into a predetermined pattern by known subtractive process, thereby forming the inner wiring patterns 10 and 11 of the build-up layers BU1 and BU2 as shown in FIG. 3.

The resin insulating layer 16 of the build-up layer BU1 is then formed by laminating the same insulating film as above onto the resin insulating layer 12 and the wiring pattern 10 as shown in FIG. 4. The resin insulating layer 17 of the build-up layer BU2 is also formed by laminating the same insulating film onto the resin insulating layer 13 and the wiring pattern 11.

The via conductor holes 18 and 19 are formed in the resin insulating layers 16 and 17 by laser irradiation. Simultaneously, the grooves 51 are formed by laser irradiation in the resin insulating layers 16 and 17 at given positions on which the wiring patterns 28 and 29 are to be formed as shown in FIG. 5. This laser irradiation process is performed by adjusting the laser output, shot number, irradiation time etc. as the via conductor holes 18 and 19 are different in depth from the grooves 51.

De-smear treatment is next performed to remove smear from the inner surfaces of the via conductor holes 18 and 19 and the grooves 51. Further, the outer surfaces of the resin insulating layers 16 and 17, the inner surfaces of the via conductor holes 18 and 19 and the inner surfaces of the grooves 51 are roughened to e.g. a surface roughness Ra of 2 μm.

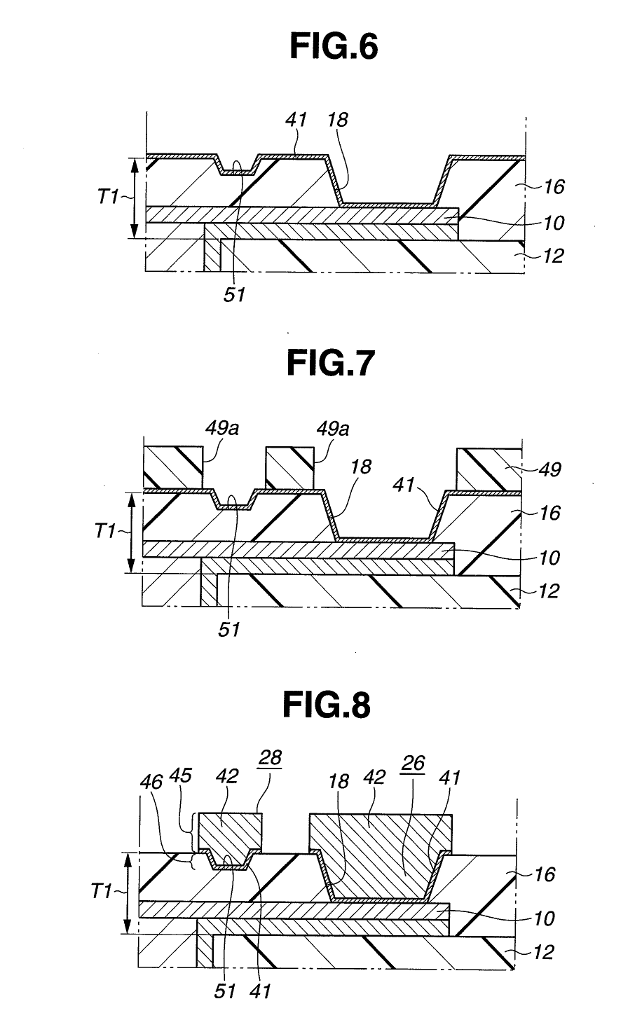

The electroless copper plating layers 41 are applied with a thickness of e.g. about 0.5 μm by known electroless copper plating process, after applying a plating catalyst, onto the outer surfaces of the resin insulating layers 16, 17 and the inner surfaces of the via conductor holes 18 and 19 and the grooves 51 as shown in FIG. 6.

Photosensitive/insulating dry films of about 25 μm in thickness are adhered to the whole surfaces of the electroless copper plating layers 41, exposed and developed, thereby forming plating resists 49 having openings 49a at given positions so as not to overlap the via conductor holes 18 and 19 and the grooves 51 as shown in FIG. 7.

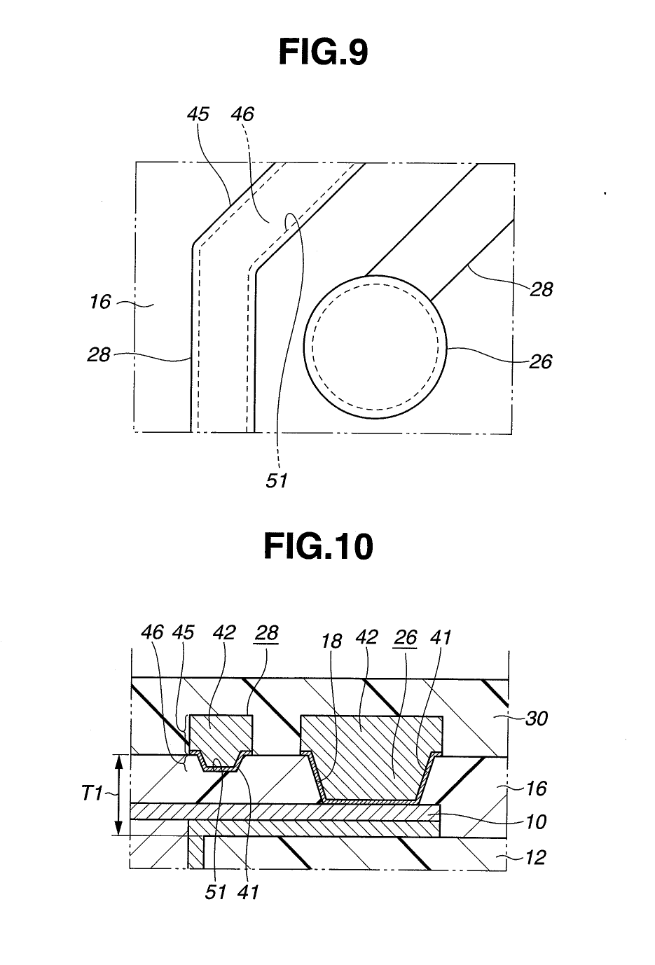

The electrolytic copper plating layers 42 are applied with a thickness of e.g. about 15 to 20 μm by known electrolytic copper plating process onto parts of the electroless copper plating layers 41 exposed through the openings 49a. After the plating resists 49 are removed by the use of a dedicated remover, the exposed parts of the electroless copper plating layers 41 are etched with a predetermined etching agent. With this, the inner wiring patterns 28 and 29 of the build-up layers BU1 and BU2 and the via conductors 26 and 27 are formed as shown in FIGS. 8 and 9.

Further, the resin insulating layer 30 of the build-up layer BU1 is formed by laminating the same insulating film as above onto the resin insulating layer 16 and the inner wiring pattern 28 as shown in FIG. 10, whereby the inner wiring pattern 28 is sandwiched between and embedded in the two adjacent resin insulating layers 16 and 30. The resin insulating layer 31 of the build-up layer BU2 is similarly formed by laminating the same insulating film onto the resin insulating layer 17 and the inner wiring pattern 29, whereby the inner wiring pattern 29 is sandwiched between and embedded in the two adjacent resin insulating layers 17 and 31.

The outer wiring patterns 34 and 35 are formed by semi-additive process. The solder resists 32, 33 of about 25 μm thickness are then applied. Nickel-gold plating is applied to the lands 34a exposed at the outer surface 32a of the solder resist 32 through the openings 36, followed by joining the solder bumps 38 to the plated lands 34a. Nickel-gold plating is also applied to the lands 35a exposed at the outer surface 33a of the solder resist 33 through the openings 37. In this way, the multilayer wiring board K1 is completed.

There is conventionally known so-called trench filling process as a technique to cut a groove in an insulating layer, fill a copper plating material in the groove and thereby form a wiring pattern. (See e.g. Japanese Laid-Open Patent Application No. 11-87276.) However, this trench filling process is difficult to perform as it is necessary in the trench filling process to remove the whole of a part of the copper plating material protruding from the insulating layer while keeping the remaining part of the copper plating material in the groove. If the process is performed with low processing accuracy, there arise problems such as wiring breakage and short-circuit.

In the first embodiment, by contrast, no plating removal process is required at the time of formation of the inner conductive portion (protruding ridge 46) of the wiring layer 28, 29 in the groove 51 of the resin insulating layer 16, 17 as mentioned above. The multilayer wiring board K1 can be thus produced relatively easily with high yield and with no risk of wiring breakage and short-circuit.

### Second Embodiment

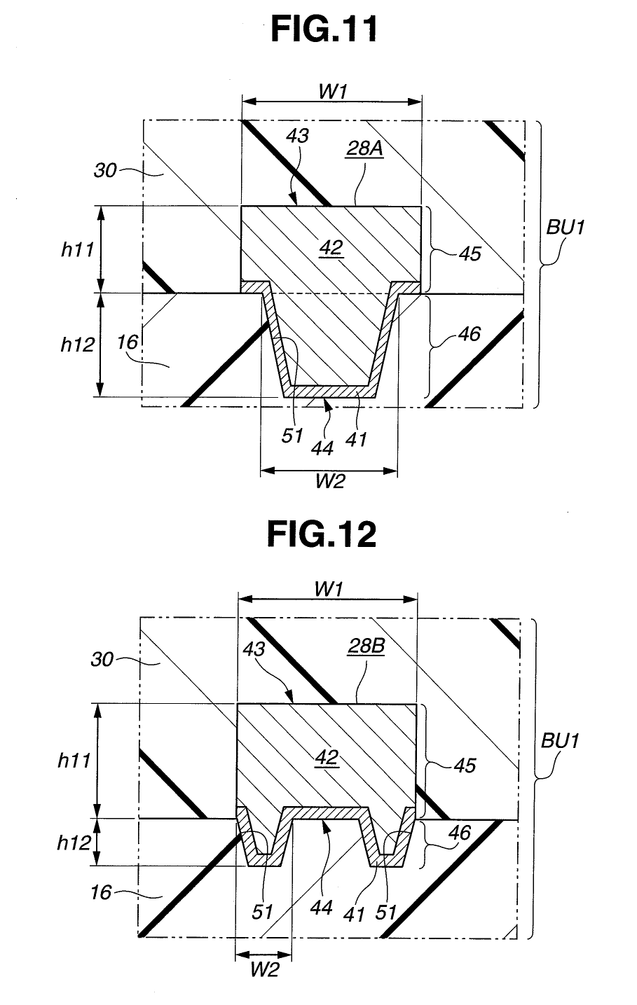

The second embodiment is structurally similar to the first embodiment, except that the build-up layer BU1 has an inner wiring pattern 28A of different form as shown in FIG. 11. The inner wiring pattern 28A of the second embodiment satisfies a relationship of h11<h12; whereas the inner wiring pattern 28 of the first embodiment satisfies a relationship of h11>h12. It is possible by satisfaction of such a dimensional relationship in the second embodiment to obtain the same effects as in the first embodiment.

It is desirable even in the second embodiment that the height ratio h11:h12 of the inner wiring pattern 28A is in the preferable range of 1:9 to 8:2, as in the case of the first embodiment. Further, the inner wiring pattern 29 may also be modified to satisfy a relationship of h11<h12 in the same manner as the inner wiring pattern 28A.

### Third Embodiment

The third embodiment is structurally similar to the first embodiment, except that the build-up layer BU1 has an inner wiring pattern 28B formed with two protruding ridges 46 as shown in FIG. 12. Two protruding ridges 46 are formed on both sides of the inner surface 44 of the inner wiring pattern 28B along the wiring direction of the inner wiring pattern 28B in the second embodiment; whereas a single protruding ridge 46 is formed on the center of the inner surface 44 of the inner wiring pattern 28, 29 in the first embodiment. In the second embodiment, two grooves 51 are recessed in the outer surface of the inner adjacent resin insulating layer 16 correspondingly to the respective protruding ridges 46 of the inner wiring pattern 28B. As the inner wiring pattern 28B is embedded in both of the two adjacent resin insulating layers 16 and 30 with the protruding ridges 46 fitted in the grooves 51, respectively, it is possible in the third embodiment to obtain the same effects as in the first embodiment. The inner wiring pattern 29 may also be modified to have two protrusion ridges 28B in the same manner as in the inner wiring pattern 28B. In this case, it is needless to say that two grooves 51 are recessed in the outer surface of the inner adjacent resin insulating layer 17 correspondingly to the respective protruding ridges 46 of the inner wiring pattern 29.

### Fourth Embodiment

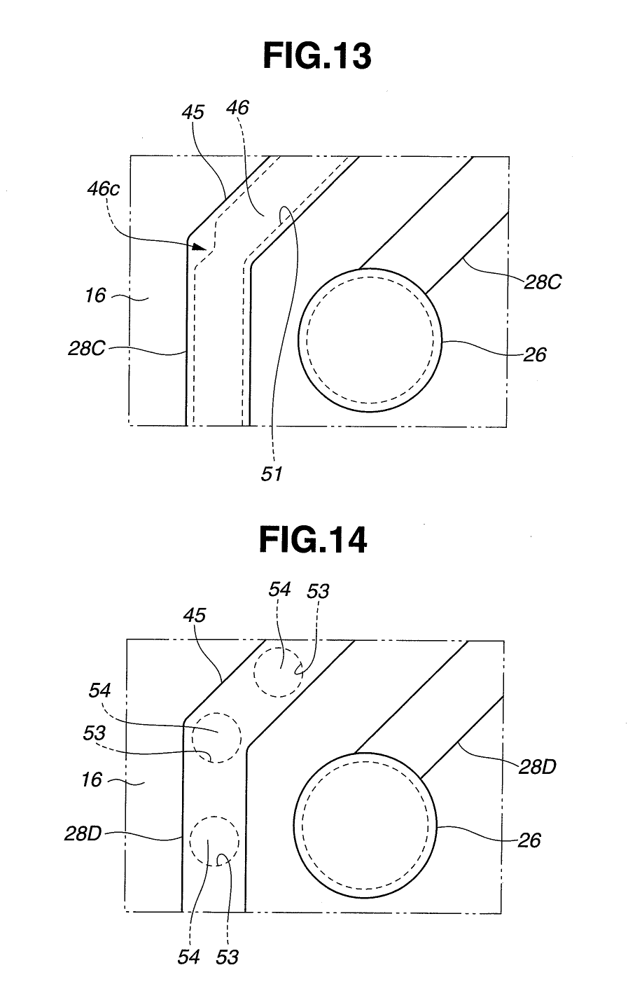

The fourth embodiment is structurally similar to the first embodiment, except that the build-up layer BU1 has an inner wiring pattern 28C formed with a protruding ridge 46 of different form as shown in FIG. 13. The protruding ridge 46 of the inner wiring pattern 28C includes a narrowed region 46c formed corresponding in position to a bent region of the inner wiring pattern 28C. Although the bent region of the wiring pattern is larger in width i.e. larger in cross section than a straight region of the wiring pattern, such an increase in cross section becomes compensated by the narrowed region 46. In consequence, the electrical resistance of the inner wiring pattern 28C can be set constant. In place of forming the narrowed region 46c, a region of the protruding ridge 46 corresponding in position to a bent region of the wiring pattern may alternatively be made smaller in height than any other region of the protruding ridge 46 such that the electrical resistance of the inner wiring pattern 28C can be set constant. It is thus possible in the fourth embodiment to obtain the same effects as in the first embodiment. The inner wiring pattern 29 may also be modified in the same manner as in the inner wiring pattern 28C such that the protruding ridge 46 of the inner wiring pattern 29 includes a narrowed region 46c formed corresponding in position to a bent region of the inner wiring pattern 29.

### Fifth Embodiment

The fifth embodiment is structurally similar to the first embodiment, except that the build-up layer BU1 has an inner wiring pattern 28D formed with a plurality of separate protrusions 54 as shown in FIG. 14. The protrusions 54 are formed on the inner surface of the inner wiring pattern 28D and aligned in the wiring direction of the inner wiring pattern 28D in the fifth embodiment; whereas a single continuous ridge-shaped protruding portion 46 is formed on the inner surface of the inner wiring pattern 28 in the first embodiment. In the fifth embodiment, a plurality of depressions 53 are formed in the outer surface of the inner adjacent resin insulating layer 16 correspondingly to the respective protrusions 54 of the inner wiring pattern 28D. There are no particular limitations on the form of the depressions 53 and protrusions 54. As the inner wiring pattern 28D is embedded in both of the two adjacent resin insulating layers 16 and 30 with the protrusions 54 fitted in the depressions 53, respectively, it is possible in the fifth embodiment to obtain the same effects as in the first embodiment.

It is herein desirable in the fifth embodiment that: the depth of the depressions 53 is smaller than the thickness T1 of the resin insulating layer 16; not only the outer surface of the resin insulating layer 16 but the inner surfaces of the depressions 53 are roughened to e.g. a surface roughness Ra of 1 μm or greater, preferably 1 to 3 μm, rather than smoothened; and the depth of the depressions 53 is set larger than the surface roughness Ra of the outer surface of the resin insulating layer 16 and the inner surfaces of the depressions 53 for the same reasons as in the first embodiment. Further, the inner wiring pattern 29 may be modified to have a plurality of separate protrusions 54 in the same manner as the inner wiring pattern 28D. In this case, it is needless to say that a plurality of depressions 53 are formed in the outer surface of the inner adjacent resin insulating layer 17 correspondingly to the respective protrusions 54 of the inner wiring pattern 29.

### Sixth Embodiment

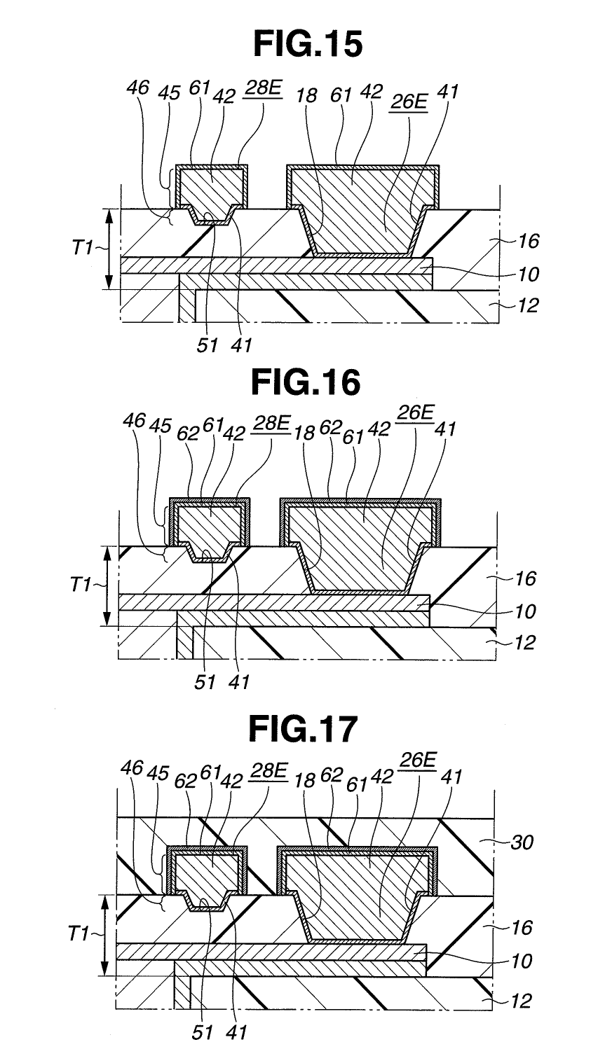

The sixth embodiment is structurally similar to the first embodiment, except that the build-up layer BU1 has an inner wiring pattern 28E that includes a metal layer arranged between the copper plating layer (electrolytic copper plating layer 42) and the outer adjacent resin insulating layer 30 as shown in FIGS. 15 to 17. Although the metal layer can be formed only on an outer surface of the copper plating layer 42, it is preferable that the metal layer is formed on not only the outer surface but side surfaces of the copper plating layer 42 so as to cover therewith the whole of a part of the copper plating layer 42 exposed from through the resin insulating layer 16 as shown in FIGS. 15 to 17 in the sixth embodiment. The metal layer can be of one kind of metal, or two or more kinds of metals, different from copper. Preferably, the metal layer is formed of a metal material having a lower velocity of diffusion into the resin insulating layer 30 than that of copper. It is possible by the formation of such a metal layer to limit the diffusion of copper from the inner wiring pattern 28E into the resin insulating layer 30 and prevent short-circuit in the inner wiring pattern 28E and between the inner wiring pattern 28E and the other conductive member.

More specifically, the metal layer is preferably a tin layer 61 in the sixth embodiment. The formation of the tin layer 61 is particularly effective in limiting the diffusion of copper from the inner wiring pattern 28E into the resin insulating layer 30 and preventing short-circuit in the inner wiring pattern 28E and between the inner wiring pattern 28E and the other conductive member. The tin layer 61 can be formed by any technique such as tin plating (electroless tin plating, electrolytic tin plating) or tin sputtering. There is no particular limitation on the thickness of the tin layer 61. The thickness of the tin layer 61 can be set to e.g. 0.1 to 0.5 μm.

In this case, it is further preferable that the inner wiring pattern 28E has a silane coupling layer 62 formed by treating an outer surface of the tin layer 61 with a silane coupling agent and thereby arranged between the tin layer 61 and the resin insulating layer 30. In the sixth embodiment, the silane coupling layer 62 is formed to cover therewith the whole of the tin layer 61. Herein, the silane coupling agent is known as a compound formed of organic substance and silicon and having two or more kinds of different functional reaction groups in its molecule. As the silane coupling agent, there can suitably be used those of vinyl type, epoxy type, amino type etc. The silane coupling agent can be selected as appropriate depending on the kind and features of the resin insulating layer. In general, it is difficult to obtain a strong bond between the resin insulating layer (organic material) and the tin layer (inorganic material). By the formation of the silane coupling layer 62, however, the tin layer 61 can be relatively firmly bonded to the resin insulating layer 30 via the silane coupling layer 62 due to chemical bond between a component of the silane coupling agent and a component of the resin insulating layer 30. It is thus possible to increase adhesion between the inner wiring pattern 28E and the resin insulating layer 30 and prevent separation of the inner wiring pattern 28E more effectively.

There is known surface roughing treatment as a technique, other than silane coupling treatment, to increase adhesion between the inner wiring pattern 28E and the resin insulating layer30. The surface roughening treatment however leads to increase in the surface roughness of the wiring pattern 28E and causes deterioration in the electrical characteristics of the wiring pattern 28E.

On the other hand, the silane coupling treatment has the advantage that the surface roughness of the wiring pattern 28E does not become increased by the silane coupling treatment so that it is possible to limit variations in the electrical resistance of the wiring pattern 28E and improve the electrical characteristics of the wiring pattern 28E.

In the sixth embodiment, the build-up layer BU1 also has a via conductor 26E provided with a tin layer 61 and a silane coupling layer 62.

The inner wiring pattern 28E can be formed as follows.

The electroless copper plating layer 41 is etched after the electroless copper plating process, the electrolytic copper plating process and the plating resist removal process as in the first embodiment. With this, the electroless copper plating layer 41 and the electrolytic copper plating layer 42 are in the state shown in FIG. 8. As shown in FIG. 15, the tin layer 61 is next formed on the whole exposed surfaces of the copper plating layer 42 of the inner wiring pattern 28E and the copper plating layer 42 of the via conductor 26 by known electroless tin plating process using a tin plating bath. The tin layer 61 may be subjected to heat treatment for smoothening as needed. In the case where the tin layer 61 has a thickness larger a predetermined thickness level, an excessive part of the tin layer 61 may be removed by washing with nitric acid. Subsequently, the silane coupling layer 62 is formed on the whole surface of the tin layer 61 by the application of a silane coupling agent (e.g. a product of Shin-etsu Chemical Co., Ltd.) as shown in FIG. 16. As shown in FIG. 17, the resin insulating layer 30 is then formed by laminating the insulating film as above onto the resin insulating layer 16 and the inner wiring pattern 28E.

The inner wiring pattern 29 (or each of the inner wiring pattern 29 and the via conductor 27) may be modified to have a tin layer 61 and a silane coupling layer 62 in the same manner as the inner wiring pattern 28E.

The entire contents of Japanese Patent Application No. 2010-074799 (filed on Mar. 29, 2010) and No. 2011-010926 (filed on Jan. 21, 2011) are herein incorporated by reference.

Although the present invention has been described with reference to the above first and second embodiments, the present invention is not limited to these specific exemplary embodiments. Various modifications and variations of the embodiments described above will occur to those skilled in the art in light of the above teachings.

There are no particular limitations on the structure of the wiring board K1, the number of the resin insulating layers and the number of the conductive wiring layers (wiring patterns) in the wiring board K1 as long as the wiring board K1 has at least one wiring pattern arranged between two adjacent resin insulating layers. Further, two build-up layers BU1 and BU2 are not necessarily provided on both sides of the core substrate 1. Only a single build-up layer may alternatively be provided on either side of the core substrate 1.

The present invention can alternatively be embodied as a so-called coreless wiring board with no core substrate 1 although the wiring board K1 is provided with the core substrate 1 in the above embodiments.

Although the resin insulating layers 12, 13, 16, 17, 30 and 31 are formed of the same kind of resin in the above embodiments, any adjacent two of the resin insulating layers 12, 13, 16, 17, 30 and 31 may alternatively be formed of different kinds of resins.

In the above embodiments, only the fine inner wiring pattern 28, 29, 28A, 28B, 28C, 28D, 28E whose maximum pattern width is 20 μm or smaller is embedded in both of the two adjacent resin insulating layers 16, 17 and 30, 31. Alternatively, the present invention may be embodied in such a manner that the inner wiring pattern whose maximum pattern width is not smaller than 20 μm is also embedded in both of the two adjacent resin insulating layers.

The scope of the invention is defined with reference to the following claims.

What is claimed is:

1. A multilayer wiring board, comprising a board body formed with two opposite main surfaces and including a first resin insulating layer, a second resin insulating layer laminated to the first resin insulating layer and a wiring pattern arranged between the first and second resin insulating layers with a first surface of the wiring pattern abutting the first resin insulating layer and a second surface of the wiring pattern abutting the second resin insulating layer, the wiring pattern extending in a plane direction of the board body and being embedded in both of the first and second resin insulating layers.

2. The multilayer wiring board according to claim 1, wherein the wiring pattern has a height ratio h11:h12 of 1:9 to 8:2 where h11 is the height of a first conductive portion of the wiring pattern embedded in the first resin insulating layer; and h12 is the height of a second conductive portion of the wiring pattern embedded in the second resin insulating layer.

3. The multilayer wiring board according to claim 1, wherein the wiring pattern has a width ratio W1:W2 of 1:1 to 9:1 where W1 is the maximum width of a first conductive portion of the wiring pattern embedded in the first resin insulating layer; and W2 is the maximum width of a second conductive portion of the wiring pattern embedded in the second resin insulating layer.

4. The multilayer wiring board according to claim 1, wherein the taper ratio of a cross section of a conductive portion of the wiring pattern embedded in the second resin insulating layer, taken perpendicular to a wiring direction of the wiring pattern, is in the range of 80% or higher.

5. The multilayer wiring board according to claim 1, wherein the second resin insulating layer has a groove formed in a surface thereof abutting the second surface of the wiring pattern along a wiring direction of the wiring pattern; and wherein the wiring pattern has a protruding ridge formed on the second surface thereof and embedded in the groove of the second resin insulating layer.

6. The multilayer wiring board according to claim 5, wherein the second resin insulating layer has a plurality of depressions formed in a surface thereof abutting the second surface of the wiring pattern; and wherein the wiring pattern has a plurality of protrusions formed on the second surface thereof and embedded in the depressions of the second resin insulating layer, respectively.

7. The multilayer wiring board according to claim 1, wherein the wiring pattern is a fine wiring pattern with a maximum line width of 20 μm or less.

8. The multilayer wiring board according to claim 5, wherein a depth of the groove is smaller than a thickness of the second resin insulating layer.

9. The multilayer wiring board according to claim 6, wherein a depth of the depressions is smaller than a thickness of the second resin insulating layer.

10. The multilayer wiring board according to claim 5, wherein the groove is formed with a roughened inner surface.

11. The multilayer wiring board according to claim 6, wherein the depressions are each formed with a roughened inner surface.

12. The multilayer wiring board according to claim 1, wherein the wiring pattern has a copper plating layer and a tin layer formed between the copper plating layer and the first resin insulating layer.

13. The multilayer wiring board according to claim 12, wherein the wiring pattern has a silane coupling layer formed between the tin layer and the first resin insulating layer.
